(19) United States
(12) Patent Application Publication
(10) Pub. No.: US 2025/0025984 A1
(43) Pub. Date: Jan. 23, 2025

(54) SUBSTRATE POLISHING METHOD, SUBSTRATE POLISHING APPARATUS, AND COMPUTER-READABLE STORAGE MEDIUM STORING PROGRAM

(71) Applicant: EBARA CORPORATION, Tokyo (JP)

(72) Inventors: Masayuki FUJIKI, Tokyo (JP); Nobuhito KIYOSAWA, Tokyo (JP)

(21) Appl. No.: 18/716,460

(22) PCT Filed: Nov. 8, 2022
(86) PCT No.: PCT/JP2022/041493

§ 371 Date: Jun. 4, 2024

(30) Foreign Application Priority Data
Dec. 14, 2021 (JP) 2021-202192

(51) Int. Cl. B24B 49/05; B24B 7/02

(52) U.S. Cl. CPC B24B 49/05; B24B 7/02

(57) ABSTRACT

The present invention relates to a substrate polishing method of polishing a substrate, such as a wafer, by pressing a polishing tape against the substrate. The substrate polishing method includes: storing an actual polishing condition for a substrate that has been polished in the past and an actual amount of use of a polishing tape under the actual polishing condition in a database (21a), with the actual polishing condition and the actual amount of use associated with each other, searching the database (21a) for an actual polishing condition that matches a preset polishing condition for a polishing-target substrate before polishing of the polishing-target substrate, determining a predicted amount of use of the polishing tape necessary for polishing the polishing-target substrate which is an actual amount of use of the polishing tape associated with the actual polishing condition that matches the preset polishing condition; comparing a remaining amount of the polishing tape to be used for polishing of the polishing-target substrate with the determined predicted amount of use; and when the remaining amount of the polishing tape is equal to or larger than the predicted amount of use, polishing the polishing-target substrate by a polishing module (4A, 4B).

### TECHNICAL FIELD

The present invention relates to a substrate polishing method of polishing a substrate, such as a wafer, and more particularly to a substrate polishing method of polishing a substrate by pressing a polishing tape against the substrate. Further, the present invention relates to a substrate polishing apparatus including a polishing module for polishing a substrate by pressing a polishing tape against the substrate. Furthermore, the present invention relates to a program for polishing a substrate with a polishing tape.

### BACKGROUND ART

Management of a surface condition of a substrate has recently attracted attention from the viewpoint of an increase in a yield in manufacturing of semiconductor devices. In a semiconductor device manufacturing process, films of various materials are formed on a silicon wafer. Therefore, an unnecessary film or surface roughness may be formed on a periphery of the substrate. These days it is a common practice to transport a substrate by holding only a periphery of the substrate with arms. With such a background, an unnecessary film, remaining on the periphery of the substrate, may peel off during various processes and may adhere to devices formed on the substrate, resulting in reduced a yield. Thus, in order to remove the unnecessary film from the periphery of the substrate, a substrate polishing apparatus is used to polish the periphery of the substrate.

This type of substrate polishing apparatus is configured to polish the periphery of the substrate by bringing a polishing tape into sliding contact with the substrate. More specifically, the substrate polishing apparatus polishes the periphery of the substrate by pressing the polishing tape against the periphery of the substrate with a polishing head while holding and rotating the substrate with a substrate holder. During polishing of the substrate, the polishing tape is fed from a tape feeding reel to a tape take-up reel via the polishing head by a polishing-tape feeding mechanism.

### CITATION LIST

### Patent Literature

Patent document 1: Japanese laid-open patent publication No. 2008-87136

### SUMMARY OF INVENTION

### Technical Problem

An end mark is located near a posterior end of the polishing tape wound around the tape feeding reel of the polishing-tape feeding mechanism. An end-mark detecting sensor that can detect this end mark is provided close to the tape feeding reel. When the end-mark detecting sensor detects the end mark of the polishing tape while the periphery of the substrate is being polished, a controller of the substrate polishing apparatus instructs the polishing-tape feeding mechanism to stop feeding of the polishing tape to the polishing head to terminate the polishing of the periphery of the substrate. In other words, the polishing of the periphery of the substrate is interrupted. An error in which polishing of the substrate is interrupted due to detection of the end mark of the polishing tape in this manner may be referred to as an “end-mark error”.

The substrate whose polishing has been interrupted due to the end-mark error has been discarded because it is difficult to determine a progress of polishing of the substrate at a point in time of the interruption and to perform additional polishing. A processing apparatus described in Patent document 1 detects a remaining amount of the polishing tape from an outer diameter of a roll of the polishing tape. However, the conventional processing apparatus cannot accurately calculate an actual amount of the polishing tape to be used for polishing of the substrate, and determines whether to replace the polishing tape based only on the remaining amount of the polishing tape. Therefore, even if the polishing tape capable of polishing a next substrate remains on the tape feeding reel, the polishing tape may be replaced.

Thus, the present invention provides a substrate polishing method capable of consuming as much polishing tape as possible and eliminating a tape end error by accurately predicting an actual amount of a polishing tape to be used for polishing of a substrate. As a result, the number of substrates which are discarded can be reduced. Further, the present invention provides a substrate polishing apparatus for polishing a substrate using such a polishing method. Furthermore, the present invention provides a computer-readable storage medium storing a program for performing such polishing method.

### Solution to Problem

In an embodiment, there is provided a substrate polishing method comprising: storing, in a database, an actual polishing condition for at least one substrate that has been polished in the past and an actual amount of use of a polishing tape under the actual polishing condition, with the actual polishing condition and the actual amount of use associated with each other; searching the database for an actual polishing condition that matches a preset polishing condition for a polishing-target substrate before polishing of the polishing-target substrate; determining a predicted amount of use of a polishing tape necessary for polishing the polishing-target substrate which is an actual amount of use of the polishing tape associated with the actual polishing condition that matches the preset polishing condition; comparing a remaining amount of the polishing tape to be used for polishing of the polishing-target substrate with the determined predicted amount of use; and when the remaining amount of the polishing tape is equal to or larger than the predicted amount of use, polishing the polishing-target substrate by a polishing module.

In an embodiment, determining the predicted amount of use comprises, when an actual polishing condition that matches the preset polishing condition does not exist in the database, determining the predicted amount of use by calculating the predicted amount of use of the polishing tape to be used for polishing of the polishing-target substrate based on the preset polishing condition.

In an embodiment, the actual polishing condition includes a polishing-head identifier for identifying a polishing head of a plurality of polishing heads that has been used in polishing of at least one substrate in the past, and the preset polishing condition includes a polishing-head identifier for identifying a polishing head to be used for polishing of the polishing-target substrate.

In an embodiment, the actual polishing condition includes a polishing-tape identifier for identifying a type of polishing tape of a plurality of types of polishing tapes that has been used in polishing of at least one substrate in the past, and the preset polishing condition includes a polishing-tape identifier for identifying a type of polishing tape to be used for polishing of the polishing-target substrate.

In an embodiment, the actual polishing condition comprises polishing conditions for a plurality of polishing processes performed in polishing of at least one substrate that has been polished in the past, the actual amount of use comprises an actual amount of use of a polishing tape that has been used from start to end of polishing including the plurality of polishing processes, and the preset polishing condition comprises polishing conditions for a plurality of polishing processes applied to polishing of the polishing-target substrate.

In an embodiment, the substrate polishing method further comprises: generating a hash value corresponding to the actual polishing condition and storing the actual amount of use and the hash value in the database, with the actual amount of use and the hash value associated with each other, and generating a searching hash value corresponding to the preset polishing condition for the polishing-target substrate and searching the database for a hash value that matches the searching hash value, wherein determining the predicted amount of use comprises determining the predicted amount of use of the polishing tape necessary for polishing the polishing-target substrate which is an actual amount of use of the polishing tape associated with the hash value that matches the searching hash value.

In an embodiment, there is provided a substrate polishing apparatus comprising: a polishing module configured to polish a substrate with a polishing tape; and a control system including a database and an arithmetic device, wherein the control system is configured to: store, in the database, an actual polishing condition for at least one substrate that has been polished in the past and an actual amount of use of a polishing tape under the actual polishing condition, with the actual polishing condition and the actual amount of use associated with each other; search the database for an actual polishing condition that matches a preset polishing condition for a polishing-target substrate before polishing of the polishing-target substrate; determine a predicted amount of use of the polishing tape necessary for polishing the polishing-target substrate which is an actual amount of use of the polishing tape associated with the actual polishing condition that matches the preset polishing condition; compare a remaining amount of the polishing tape to be used for polishing of the polishing-target substrate with the determined predicted amount of use; and when the remaining amount of the polishing tape is equal to or larger than the predicted amount of use, instruct the polishing module to polish the polishing-target substrate.

In an embodiment, the control system is configured to calculate the predicted amount of use of the polishing tape to be used for polishing of the polishing-target substrate based on the preset polishing condition when an actual polishing condition that matches the preset polishing condition does not exist in the database.

In an embodiment, the actual polishing condition includes a polishing-head identifier for identifying a polishing head of a plurality of polishing heads that has been used in polishing of at least one substrate in the past, and the preset polishing condition includes a polishing-head identifier for identifying a polishing head to be used for polishing of the polishing-target substrate.

In an embodiment, the actual polishing condition includes a polishing-tape identifier for identifying a type of polishing tape of a plurality of types of polishing tapes that has been used in polishing of at least one substrate in the past, and the preset polishing condition includes a polishing-tape identifier for identifying a type of polishing tape to be used for polishing of the polishing-target substrate.

In an embodiment, the actual polishing condition comprises polishing conditions for a plurality of polishing processes performed in polishing of at least one substrate that has been polished in the past, the actual amount of use comprises an actual amount of use of a polishing tape that has been used from start to end of polishing including the plurality of polishing processes, and the preset polishing condition comprises polishing conditions for a plurality of polishing processes applied to polishing of the polishing-target substrate.

In an embodiment, the control system is configured to: generate a hash value corresponding to the actual polishing condition and store the actual amount of use and the hash value in the database, with the actual amount of use and the hash value associated with each other; generate a searching hash value corresponding to the preset polishing condition for the polishing-target substrate and search the database for a hash value that matches the searching hash value; and determine the predicted amount of use of the polishing tape necessary for polishing the polishing-target substrate which is an actual amount of use of the polishing tape associated with the hash value that matches the searching hash value.

In an embodiment, there is provided a computer-readable storage medium storing a program for instructing a control system to perform the steps of: storing, in the database, an actual polishing condition for at least one substrate that has been polished in the past and an actual amount of use of a polishing tape under the actual polishing condition, with the actual polishing condition and the actual amount of use associated with each other; searching the database for an actual polishing condition that matches a preset polishing condition for a polishing-target substrate before polishing of the polishing-target substrate, determining a predicted amount of use of the polishing tape necessary for polishing the polishing-target substrate which is an actual amount of use of the polishing tape associated with the actual polishing condition that matches the preset polishing condition; comparing a remaining amount of the polishing tape to be used for polishing of the polishing-target substrate with the determined predicted amount of use; and when the remaining amount of the polishing tape is equal to or larger than the predicted amount of use, instructing the polishing module to polish the polishing-target substrate.

### Advantageous Effects of Invention

According to the present invention, the actual amount of use of the polishing tape associated with the actual polishing condition that matches the polishing condition for the polishing-target substrate is used as the predicted amount of use of the polishing tape. Therefore, the substrate polishing apparatus can determine an accurately predicted amount of use of the polishing tape which reflects a change in tape feeding speed during polishing of the substrate, a feeding amount of the polishing tape when the polishing head moves between head positions, and a feeding amount of the polishing tape in a transition period between different polishing processes.

Further, according to the present invention, the substrate polishing apparatus can consume as much polishing tape as possible and can eliminate a tape end error by comparing the remaining amount of the polishing tape with the determined predicted amount of use before polishing of the polishing-target substrate. As a result, the number of substrates which are discarded can be reduced.

### BRIEF DESCRIPTION OF DRAWINGS

FIG. 1 is a plan view showing an embodiment of a substrate polishing apparatus;

FIG. 2A is an enlarged cross-sectional view showing a periphery of a substrate;

FIG. 2B is an enlarged cross-sectional view showing a periphery of a substrate:

FIG. 3 is a schematic diagram showing an embodiment of a polishing module;

FIG. 4 is a schematic diagram showing an embodiment of a polishing head;

FIG. 5 is a plan view showing an embodiment of tilting mechanisms;

FIG. 6 is a diagram illustrating continuous polishing of the substrate;

FIG. 7 is a diagram illustrating fixed polishing of the substrate;

FIG. 8 is a flowchart illustrating an embodiment of polishing processes of the substrate:

FIG. 9 is a table showing an example of polishing conditions for the polishing processes shown in FIG. 8:

FIG. 10 is a flowchart illustrating an embodiment of processing operations of the substrate polishing apparatus:

FIG. 11 is a diagram illustrating a process of storing, in a database, actual polishing conditions and actual amounts of use of a polishing tape for substrates that have been polished in the past,

FIG. 12 is a diagram illustrating a process of searching the database for an actual polishing condition that matches a preset polishing condition for a polishing-target substrate and determining a predicted amount of use,

FIG. 13 is a diagram illustrating a method of searching using a searching hash value; and

FIG. 14 is a plan view showing an embodiment of arrangements of a plurality of polishing-target substrates.

### DESCRIPTION OF EMBODIMENTS

Hereinafter, embodiments of the present invention will be described with reference to the drawings.

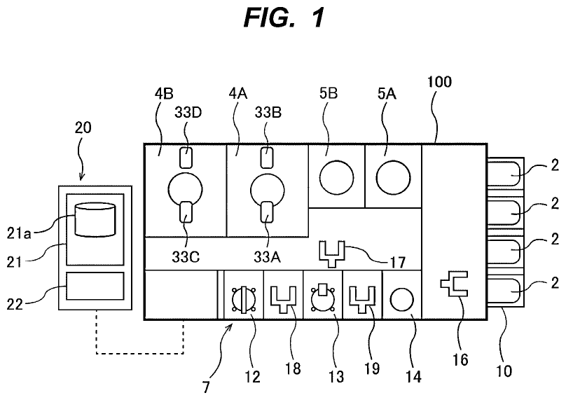

FIG. 1 is a plan view showing an embodiment of a substrate polishing apparatus. The substrate polishing apparatus of this embodiment is an apparatus for polishing a periphery of a substrate including a bevel portion of the substrate. In one embodiment, the substrate polishing apparatus may be an apparatus for polishing a notch portion of the substrate. The substrate polishing apparatus includes polishing modules 4A and 4B, waiting stages 5A and 5B, a cleaning-drying section 7, a load port 10, a first transfer robot 16, a second transfer robot 17, a third transfer robot 18, and a fourth transfer robot 19. The polishing modules 4A and 4B, the waiting stages 5A and 5B, the cleaning-drying section 7, the first transfer robot 16, the second transfer robot 17, the third transfer robot 18, and the fourth transfer robot 19 are arranged in a housing 100.

Polishing-target substrates are housed in substrate cassettes 2, and the substrate cassettes 2 are placed on the load port 10. The first transfer robot 16 is arranged adjacent to the load port 10. The first transfer robot 16 removes a substrate to be polished from the substrate cassette 2 on the load port 10, and transports the substrate to the second transfer robot 17.

In this embodiment, the substrate polishing apparatus includes two polishing modules 4A and 4B, while in one embodiment, the substrate polishing apparatus may include one polishing module, or three or more polishing modules. Similarly, in this embodiment, the substrate polishing apparatus includes two waiting stages 5A and 5B, while in one embodiment, the substrate polishing apparatus may include one waiting stage, or three or more waiting stages.

The polishing modules 4A and 4B, and the waiting stages 5A and 5B are arranged along a longitudinal direction of the housing 100. The polishing-target substrate is placed on the waiting stage 5A or 5B before being polished by the polishing module 4A or 4B. In one embodiment, the waiting stage 5A and/or the waiting stage 5B may include a notch aligner (not shown). The notch aligner is a device configured to detect a notch of the substrate and align the notch of the substrate to a predetermined position. The specific configuration of the notch aligner is not particularly limited as long as the notch aligner can detect the notch of the substrate and align the notch of the substrate to the predetermined position.

A periphery of the polishing-target substrate is polished by at least one of the polishing modules 4A and 4B. The periphery of the polishing-target substrate may be polished by either the polishing module 4A or 4B, or by the two polishing modules 4A and 4B.

The polishing module 4A includes two polishing heads 33A and 33B. Polishing of the polishing-target substrate in the polishing module 4A may be performed by either the polishing head 33A or 33B, or by the two polishing heads 33A and 33B. The polishing module 4B includes two polishing heads 33C and 33D. Polishing of the polishing-target substrate in the polishing module 4B may be performed by either the polishing head 33C or 33D, or by the two polishing heads 33C and 33D.

The second transfer robot 17 is arranged adjacent to the polishing modules 4A and 4B, the waiting stages 5A and 5B, and the cleaning-drying section 7. The second transfer robot 17 is configured to receive the substrate from the first transfer robot 16, and transport the substrate between the polishing modules 4A, 4B and the waiting stages 5A, 5B. Further, the second transfer robot 17 is configured to transport the substrate received from the polishing modules 4A and 4B to the cleaning-drying section 7.

The cleaning-drying section 7 includes a first cleaning module 12 and a second cleaning module 13 configured to clean the substrate whose periphery has been polished by the polishing module(s) 4A and/or 4B, and a doing module 14 configured to dry the cleaned substrate. The first cleaning module 12, the second cleaning module 13, and the doing module 14 are arranged along the longitudinal direction of the housing 100. The first cleaning module 12 is configured to perform scrub cleaning with use of a roll-shaped sponge member. The second cleaning module 13 is configured to perform scrub cleaning with use of a pencil-shaped sponge member. In this embodiment, the cleaning-drying section 7 includes the first cleaning module 12 and the second cleaning module 13, while in one embodiment, the cleaning-drying section 7 may include either the first cleaning module 12 or the second cleaning module 13.

The third transfer robot 18 is disposed between the first cleaning module 12 and the second cleaning module 13. The fourth transfer robot 19 is disposed between the second cleaning module 13 and the doing module 14. The third transfer robot 18 is configured to transport the substrate between the first cleaning module 12 and the second cleaning module 13. The fourth transfer robot 19 is configured to transport the substrate between the second cleaning module 13 and the doing module 14.

The substrate polishing apparatus polishes a plurality of substrates by sequentially performing polishing of the peripheries of the substrates by the polishing module(s) 4A and/or 4B, and cleaning and drying of the substrates by the cleaning-diving section 7.

The substrate polishing apparatus further includes a control system 20 electrically coupled to the polishing modules 4A and 4B, the waiting stages 5A and 5B, the cleaning-drying section 7, the first transfer robot 16, the second transfer robot 17, the third transfer robot 18, and the fourth transfer robot 19. The control system 20 is configured to control operations of the polishing modules 4A and 4B, the waiting stages 5A and 5B, the cleaning-drying section 7, the first transfer robot 16, the second transfer robot 17, the third transfer robot 18, and the fourth transfer robot 19.

The control system 20 includes a memory 21 storing a database 21a, which will be described later, and programs, and an arithmetic device 22 configured to perform arithmetic operations according to the programs. The memory 21 includes a main memory (e.g., a random access memory) to which the arithmetic device 22 is accessible, and an auxiliary memory (e.g., a hard disk drive or a solid state drive) configured to store the database 21a and the programs. The arithmetic device 22 includes a CPU (central processing unit), a GPU (graphic processing module), or the like configured to perform the arithmetic operations according to instructions contained in the programs stored in the memory 21.

In one embodiment, the control system 20 may include a display screen (not shown) configured to display processing results and processed data generated by the arithmetic device 22, and an input device (not shown) configured to input data, programs, and various information to the memory 21.

The control system 20 includes at least one computer. For example, the control system 20 may be an edge server coupled to the substrate polishing apparatus through a communication line, or may be a cloud server coupled to the substrate polishing apparatus through a network, such as the Internet. The control system 20 may be a combination of a plurality of servers. For example, the control system 20 may be a combination of an edge server and a cloud server coupled to each other by a communication network, such as the Internet or a local area network, or a combination of a plurality of servers not coupled by a communication network. However, the specific configuration of the control system 20 is not limited to these examples. In one embodiment, the control system 20 may be constituted of a plurality of devices, each of which may include the memory 21 and the arithmetic device 22.

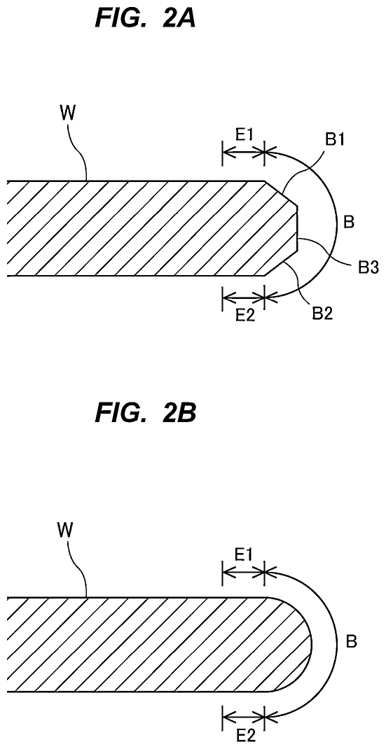

Next, details of configurations of the polishing modules 4A and 4B will be described. Since the polishing modules 4A and 4B have basically the same configuration, the polishing module 4A will be described below. The polishing module 4A of this embodiment is configured to polish a periphery of a substrate W shown in FIG. 2A or 2B. FIGS. 2A and 2B are enlarged cross-sectional views each showing the periphery of the substrate W. More specifically, FIG. 2A is a cross-sectional view of a substrate W of a so-called straight type, and FIG. 2B is a cross-sectional view of a substrate W of a so-called round type. A bevel portion B has a beveled shape or a rounded shape.

In the substrate W of FIG. 2A, the bevel portion B is an outermost peripheral surface constituted of an upper slope surface (or an upper bevel portion) B1, a lower slope surface (or a lower bevel portion) B2, and a side portion (or an apex) B3 of the substrate W. In the substrate W of FIG. 2B, the bevel portion B is a portion constituting an outermost peripheral surface of the substrate W and has a curved cross section. A top-edge portion E1 is an annular flat portion located radially inwardly of the bevel portion B. A bottom-edge portion E2 is an annular flat portion located at an opposite side from the top-edge portion E1 and located radially inwardly of the bevel portion B. The top-edge portion E1 may include a region in which devices are formed. In this specification, the periphery of the substrate W refers to a region including any one of the top-edge portion E1, the bevel portion B, and the bottom-edge portion E2.

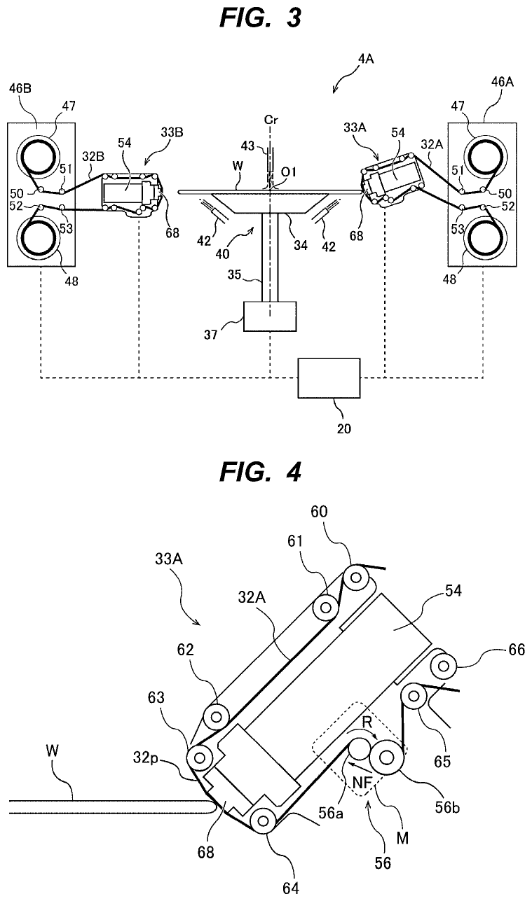

FIG. 3 is a schematic diagram showing an embodiment of the polishing module 4A. The polishing module 4A includes a substrate holder 40 configured to hold and rotate the polishing-target substrate W, the two polishing heads 33A and 33B configured to press polishing tapes 32A and 32B against the periphery of the substrate W, which is rotated by the substrate holder 40, to polish the periphery of the substrate W, lower supply nozzles 42 configured to supply liquid onto a lower surface of the substrate W, and an upper supply nozzle 43 configured to supply liquid onto an upper surface of the substrate W. An example of the liquid supplied to the substrate W is pure water. During polishing of the substrate W, the liquid is supplied from the lower supply nozzle(s) 42 onto the lower surface of the substrate W, and the liquid is supplied from the upper supply nozzle 43 onto the upper surface of the substrate W.

In this embodiment, the polishing module 4A includes two polishing heads 33A and 33B, while in one embodiment, the polishing module 4A may include one polishing head, or three or more polishing heads. The periphery of the polishing-target substrate W is polished by at least one of the polishing heads 33A and 33B of the polishing module 4A. When the polishing head 33A is located in a polishing position, the polishing head 33B is located in a retracted position. When the polishing head 33B is located in a polishing position, the polishing head 33A is located in a retracted position.

FIG. 3 shows the polishing head 33A located in the polishing position and the polishing head 33B located in the retracted position. The polishing head 33A is oriented toward the periphery of the substrate W. The substrate holder 40 holds the substrate W. The substrate holder 40 includes a holding stage 34 configured to hold the substrate W by vacuum suction, a shaft 35 coupled to a center portion of the holding stage 34, and a holding-stage driving mechanism 37 configured to rotate and vertically move the holding stage 34. The holding-stage driving mechanism 37 is configured to rotate the holding stage 34 about its or (axis Cr, and is configured to move the holding stage 34 in a vertical direction along the axis Cr.

The substrate W is placed on a substrate holding surface of the holding stage 34 by the second transfer robot 17 (see FIG. 1) such that the center O1 of the substrate W is located on the axis Cr of the holding stage 34. The substrate holder 40 can rotate the substrate W about the axis Cr of the holding stage 34 (i.e., an axis of the substrate W), and can vertically move the substrate W along the axis Cr of the holding stage 34.

The polishing module 4A further includes a polishing-tape feeding mechanism 46A configured to feed the polishing tape 32A to the polishing head 33A and collect the polishing tape 32A from the polishing head 33A. The polishing module 4A further includes a polishing-tape feeding mechanism 46B configured to feed the polishing tape 32B to the polishing head 33B and collect the polishing tape 32B from the polishing head 33B. Since the polishing-tape feeding mechanisms 46A and 46B have basically the same configuration, the polishing-tape feeding mechanism 46A will be described below.

The polishing-tape feeding mechanism 46A includes a tape feeding reel 47 configured to feed the polishing tape 32A to the polishing head 33A, and a tape take-up reel 48 configured to collect the polishing tape 32A that has been used in polishing of the substrate W. Not-shown (tension motors are coupled to the tape feeding reel 47 and the tape take-up reel 48, respectively. The tension motors are configured to apply predetermined torque(s) to the tape feeding reel 47 and the tape take-up reel 48, so that a predetermined tension can be applied to the polishing tape 32A.

The polishing tape 32A is fed to the polishing head 33A such that a polishing surface of the polishing tape 32A faces the periphery of the substrate W. The polishing tape 32A is fed to the polishing head 33A from the tape feeding reel 47, and the used polishing tape 32A is collected by the tape take-up reel 48. The polishing-tape feeding mechanism 46A further includes a plurality of guide rollers 50, 51, 52, and 53 configured to support the polishing tape 32A. An advancing direction of the polishing tape 32A is guided by the guide rollers 50, 51, 52, and 53.

Next, details of configurations of the polishing heads 33A and 33B will be described. Since the polishing heads 33A and 33B have basically the same configuration, the polishing head 33A will be described below. Configurations of the polishing heads 33C and 33D of the polishing module 4B also have basically the same configuration as that of the polishing head 33A described below, and duplicated descriptions will be omitted. FIG. 4 is a schematic diagram showing an embodiment of the polishing head 33A. The polishing head 33A includes a tape advancing device 56 configured to advance the polishing tape 32A from the tape feeding reel 47 (see FIG. 3) to the tape take-up reel 48 (see FIG. 3). The polishing head 33A includes a plurality of guide rollers 60, 61, 62, 63, 64, 65, and 66. These guide rollers 60, 61, 62, 63, 64, 65, and 66 are configured to guide the polishing tape 32A such that the polishing tape 32A advances in a direction perpendicular to a tangential direction of the substrate W.

The tape advancing device 56 provided in the polishing head 33A includes a tape advancing roller 56a, a tape nipping roller 56b, and a tape advancing motor M configured to rotate the tape advancing roller 56a. The tape advancing motor M is disposed in a side surface of the polishing head 33A, and a tape advancing roller 56a is attached to a rotating shaft of the tape advancing motor M. The tape nipping roller 56b is arranged next to the tape advancing roller 56a. The tape nipping roller 56b is supported by a not-shown mechanism so as to generate force in a direction indicated by an arrow NF in FIG. 4 (i.e., a direction toward the tape advancing roller 56a), and is configured to press the tape advancing roller 56a.

When the tape advancing motor M rotates in a direction indicated by an arrow R in FIG. 4, the tape advancing roller 56a rotates and enables the polishing tape 32A to advance in a longitudinal direction thereof. The tape nipping roller 56b is configured to be rotatable about its own axis, and is configured to be rotated as the polishing tape 32A advances. The tape advancing motor M has a rotary encoder (not shown) configured to be able to count the number of rotations of the tape advancing motor M.

The polishing head 33A further includes a pressing member 68 configured to press the polishing tape 32A against the substrate W. and an air cylinder 54 as an actuator configured to move the pressing member 68 toward the periphery of the substrate W. A pressing force on the polishing tape 32A against the substrate W is regulated by controlling a pressure of air supplied to the air cylinder 54. The pressing member 68 is arranged at a back side of a polishing surface 32p (surface having abrasive grains) of the polishing tape 32A. When the pressing member 68 is moved toward the substrate W by the air cylinder 54, the pressing member 68 presses the polishing tape 32A against the periphery of the substrate W from the back side of the polishing tape 32A, so that the polishing head 33A polishes the periphery of the substrate W.

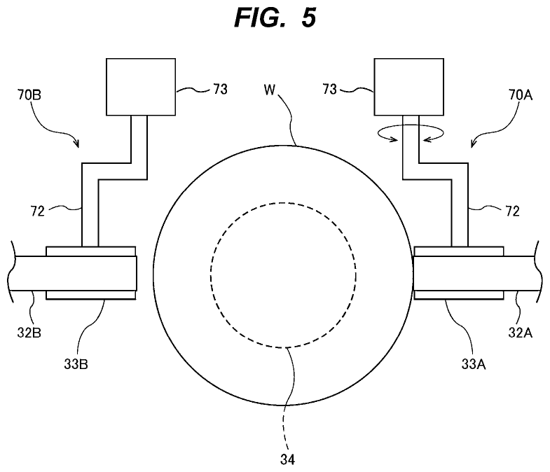

FIG. 5 is a plan view showing an embodiment of tilting mechanisms 70A and 70B configured to tilt the polishing heads 33A and 33B. As shown in FIG. 5, the polishing module 4A further includes two tilting mechanisms 70A and 70B configured to tilt the polishing heads 33A and 33B at predetermined angles, respectively. The tilting mechanism 70A is coupled to the polishing head 33A, and the tilting mechanism 70B is coupled to the polishing head 33B. Since the tilting mechanism 70A configured to tilt the polishing head 33A and the tilting mechanism 70B configured to tilt the polishing head 33B have basically the same configuration, the tilting mechanism 70A will be described below.

The tilting mechanism 70A is configured to tilt the polishing head 33A with respect to the substrate holding surface of the holding stage 34. More specifically, the tilting mechanism 70A includes a crank arm 72 coupled to the polishing head 33A, and an arm rotating device 73 configured to rotate the crank arm 72. One end of the crank arm 72 is located at substantially the same height as that of the substrate holding surface of the holding stage 34, and is coupled to the arm rotating device 73. The other end of the crank arm 72 is coupled to the polishing head 33A.

When the arm rotating device 73 rotates the crank arm 72, the entire polishing head 33A can be tilted with respect to the substrate W on the substrate holding surface of the holding stage 34 at a predetermined tilt speed. Therefore, the polishing head 33A can polish the periphery of the substrate W while the polishing head 33A is tilted at the predetermined tilt speed. The tilt speed is an angle at which the polishing head tilts per unit time. For example, a unit of tilt speed is represented in “degree/minute”. Further, the tilting mechanism 70A is configured to maintain a predetermined angle of inclination of the polishing head 33A. Therefore, the polishing head 33A can polish the periphery of the substrate W with the predetermined angle of inclination maintained. The specific configuration of the tilting mechanism 70A is not limited to the embodiment shown in FIG. 5 as long as the polishing head 33A can be tilted with respect to the substrate holding surface of the holding stage 34 and the substrate W.

The polishing module 4A is electrically coupled to the control system 20 configured to control operations of each component of the polishing module 4A. The polishing heads 33A and 33B, the substrate holder 40, the lower supply nozzles 42, the upper supply nozzle 43, the polishing-tape feeding mechanisms 46A and 46B, and the tilting mechanisms 70A and 70B are electrically coupled to the control system 20. Operations of the polishing heads 33A and 33B, the substrate holder 40, the lower supply nozzles 42, the upper supply nozzle 43, the polishing-tape feeding mechanisms 46A and 46B, and the tilting mechanisms 70A and 70B are controlled by the control system 20.

Polishing of the periphery of the substrate by the polishing modules 4A and 4B is classified into two polishing modes, which are continuous polishing and fixed polishing, according to the operations of the polishing head during polishing of the substrate. In this specification, a polishing mode of polishing the periphery of the substrate while the polishing head is continuously tiled at the predetermined tilt speed by the tilting mechanism is referred to as “continuous polishing”. Further, a polishing mode of polishing the periphery of the substrate while the polishing head is maintained at the predetermined angle of inclination by the tilting mechanism is referred to as “fixed polishing”.

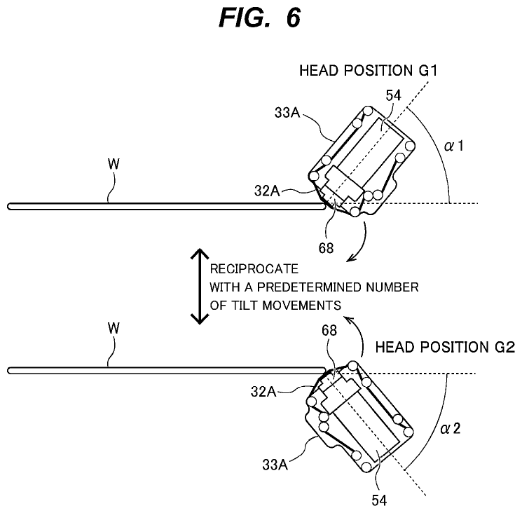

FIG. 6 is a diagram illustrating the polishing head 33A of the polishing module 4A when performing the continuous polishing on the periphery of the substrate W. In the continuous polishing, the polishing tape 32A is pressed against the periphery of the substrate W by the polishing head 33A while the angle of inclination of the polishing head 33A is continuously changed by the tilting mechanism 70A (see FIG. 5). More specifically, as shown in FIG. 6, the tilting mechanism 70A continuously changes the angle of inclination of the polishing head 33A at the predetermined tilt speed from a head position G1 where the angle of inclination of the polishing head 33A is α1 (e.g., 60 degrees) to a head position G2 where the angle of inclination of the polishing head 33A is α2 (e.g., −60 degrees). While the tilting mechanism 70A is tilting the polishing head 33A, the pressing member 68 of the polishing head 33A presses the polishing tape 32A against the periphery of the substrate W by the air cylinder 54. In this manner, the polishing head 33A polishes the periphery of the substrate W. The tilting mechanism 70A reciprocates the polishing head 33A between the head position G1 and the head position G2 with a predetermined number of tilt movements. During polishing of the substrate W, the polishing tape 32A is fed at a predetermined speed by the tape advancing device 56 (see FIG. 4).

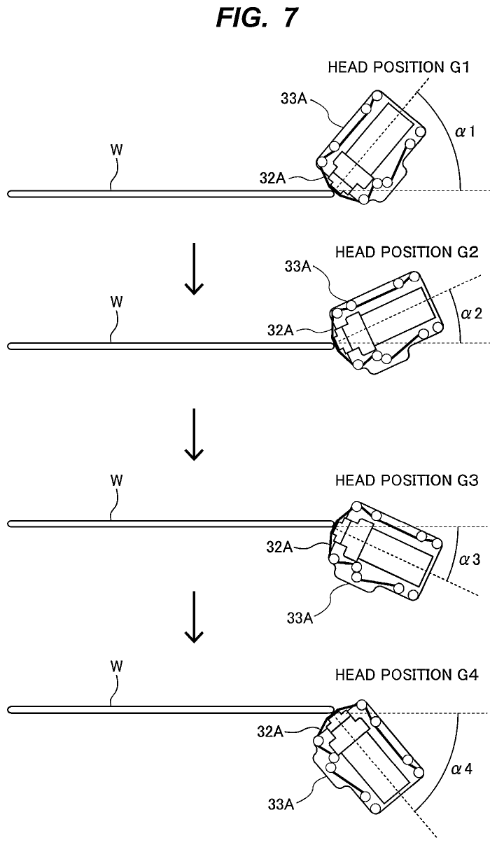

FIG. 7 is a diagram illustrating the polishing head 33A of the polishing module 4A when performing the fixed polishing on the periphery of the substrate W. In an example of the fixed polishing shown in FIG. 7, the polishing tape 32A is pressed against the periphery of the substrate W by the polishing head 33A while the polishing head 33A is sequentially maintained at a plurality of predetermined angles of inclination by the tilting mechanism 70A shown in FIG. 5. More specifically, as shown in FIG. 7, the tilting mechanism 70A maintains the polishing head 33A at a head position G1 where the angle of inclination of the polishing head 33A is α1 (e.g., 60 degrees) for a predetermined polishing time. Next, the tilting mechanism 70A moves the polishing head 33A from the head position G1 to a head position G2 where the angle of inclination of the polishing head 33A is α2 (e.g., 30 degrees) at a predetermined tilt speed, and maintains the polishing head 33A at the head position G2 for a predetermined polishing time. Next, the tilting mechanism 70A moves the polishing head 33A from the head position G2 to a head position G3 where the angle of inclination of the polishing head 33A is α3 (e.g., −30 degrees) at a predetermined tilt speed, and maintains the polishing head 33A at the head position G3 for a predetermined polishing time. Further, the tilting mechanism 70A moves the polishing head 33A from the head position G3 to a head position G4 where the angle of inclination is α4 (e.g., −60 degrees) at a predetermined tilt speed, and maintains the polishing head 33A at the head position G4 for a predetermined polishing time.

While the polishing head 33A is moving between the head positions, the polishing tape 32A is separated from the substrate W. After the polishing head 33A is located at the predetermined head position, the polishing head 33A presses the polishing tape 32A against the substrate W to polish the periphery of the substrate W. During polishing of the substrate W and while the polishing head 33A moves between the head positions, the polishing tape 32A is fed at the predetermined speed by the tape advancing device 56 (see FIG. 4). In one embodiment, the polishing head 33A may press the polishing tape 32A against the substrate W to polish the periphery of the substrate W while moving between the head positions.

In this embodiment, the number of head positions of the polishing head 33A is four, from the head position G1 to the head position G4, while in one embodiment, the number of head positions of the polishing head 33A may be three or less, or five or more.

The substrate polishing apparatus of this embodiment may polish the substrate W with different types of polishing tapes fed to the polishing heads 33A and 33B of the polishing module 4A and the polishing heads 33C and 33D of the polishing module 4B. For example, the entire periphery of the substrate W including the top-edge portion E1, the bevel portion B, and the bottom-edge portion E2 (see FIGS. 2A and 2B) may be rough-polished by the polishing head 33A of the polishing module 4A, and then the entire periphery of the substrate W including the top-edge portion E1, the bevel portion B, and the bottom-edge portion E2 may be finish-polished by the polishing head 33B. In this case, a polishing tape for rough-polishing (i.e., a polishing tape with large abrasive grains) is fed to the polishing head 33A from the polishing-tape feeding mechanism 46A, and a polishing tape for finish-polishing (i.e., a polishing tape with small abrasive grains) is fed to the polishing head 33B from the polishing-tape feeding mechanism 46B. Alternatively, the entire periphery of the substrate W including the top-edge portion E1, the bevel portion B, and the bottom-edge portion E2 may be rough-polished by the polishing head 33A of the polishing module 4A, and then the top-edge portion E1 may be finish-polished by the polishing head 33B. Thereafter, the bevel portion B may be finish-polished by the polishing head 33C of the polishing module 4B, and then the bottom-edge portion E2 may be finish-polished by the polishing head 33D.

Polishing of the periphery of the substrate W is performed under a preset polishing condition. The preset polishing condition is input to the control system 20, for example, by a user via an input device (not shown), and is stored in the memory 21 of the control system 20. The control system 20 controls the operations of the polishing module 4A (and/or the polishing module 4B) according to the polishing condition stored in the memory 21 to cause the polishing module 4A (and/or the polishing module 4B) to perform polishing of the periphery the substrate W.

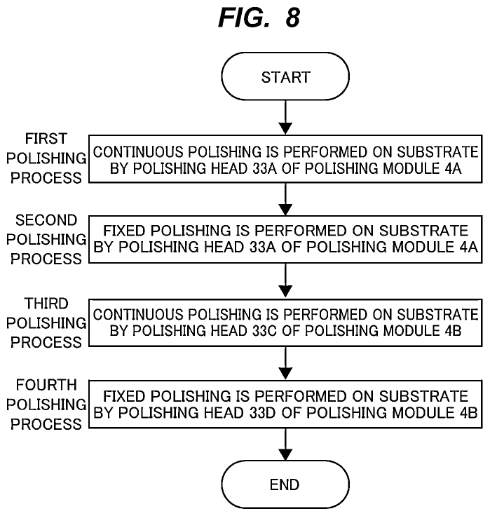

FIG. 8 is a flowchart illustrating an embodiment of polishing processes of the substrate W. In this embodiment, polishing of the substrate W includes four polishing processes which are a first polishing process, a second polishing process, a third polishing process, and a fourth polishing process. First, in the first polishing process, continuous polishing is performed on the substrate by the polishing head 33A of the polishing module 4A. In the second polishing process, fixed polishing is then performed on the substrate W by the same polishing head 33A. Thereafter, continuous polishing is performed on the substrate W by the polishing head 33C of the polishing module 4B. Finally, fixed polishing is performed on the substrate W by the polishing head 33D of the polishing module 4B. As in the first polishing process and the second polishing process, continuous polishing and fixed polishing, which are different polishing modes, may be performed on one substrate by one polishing head 33A. In one embodiment, polishing of the substrate W may include only a single polishing process.

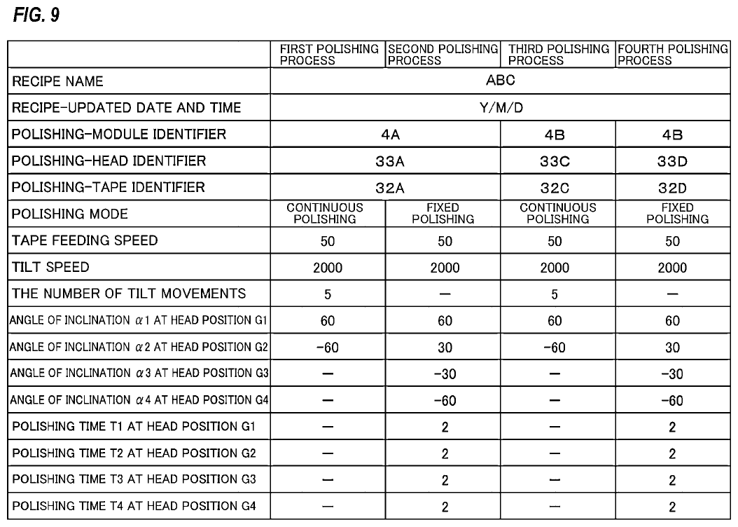

FIG. 9 is a table showing an example of polishing conditions for the polishing processes shown in FIG. 8. Each polishing condition of this embodiment include a recipe name, recipe update date and time, a polishing-module identifier, a polishing-head identifier, a polishing-tape identifier, a polishing mode, a tape feeding speed, a tilt speed, the number of tilt movements, angles of inclination α1 to α4 at the head positions, and polishing times T1 to T4 at the head positions. Parameters shown in FIG. 9 are an example of the polishing condition, and the polishing condition is not limited to these examples as long as the polishing condition includes parameters necessary for controlling the operations of the polishing modules 4A and 4B.

The recipe name is a name (e.g., a character string) of a polishing recipe created by a user, and functions as an identifier that identifies the polishing condition. The polishing recipe includes a combination of parameter values of the polishing condition in all polishing processes performed by the polishing modules 4A and 4B. The recipe name is associated with each parameter value of the polishing condition, and each parameter value is uniquely identified by the recipe name. In the embodiment shown in FIG. 9, the polishing recipe represented by the recipe name “ABC” includes parameter values included in the polishing conditions of the first polishing process to the fourth polishing process.

The recipe update date and time is date and time when the parameter value of the polishing condition associated with the recipe name is updated. When a polishing condition with a new recipe name is registered in the control system 20, or when the parameter value of the polishing condition associated with an recipe name already registered is changed, the recipe update date and time is automatically registered (recorded) by the control system 20.

The polishing-module identifier is a value (e.g., a numerical number, a character, or a combination thereof) for identifying the polishing module used in each polishing process. In one example, the polishing-module identifiers are “4A” and “4B”.

The polishing-head identifier is a value (e.g., a numerical number, a character, or a combination thereof) for identifying the polishing head used in each polishing process. In one example, the polishing-head identifiers are “33A”, “33B”, “33C”, and “33D”.

The polishing-tape identifier is a value (e.g., a numerical number, a character, or a combination thereof) for identifying a type of the polishing tape used in each polishing process. There are various types of the polishing tape depending on a roughness of the abrasive grains on the polishing surface, a width of the polishing tape, etc. In one example, the polishing-tape identifiers are “32A”. “32B”, “32C”, and “32D”.

The polishing mode is represented by a value (e.g., a numerical number, a character, or a combination thereof) for identifying the polishing mode applied in each polishing process. In the embodiment shown in FIG. 9, the polishing mode of the first polishing process is “continuous polishing”, the polishing mode of the second polishing process is “filed polishing”, the polishing mode of the third polishing process is “continuous polishing”, and the polishing mode of the fourth polishing process is “fixed polishing”.

The tape feeding speed is represented by a set value of a feeding speed of the polishing tape in each polishing process. In the embodiment shown in FIG. 9, the polishing-tape feeding speed is “50 mm/minute”.

The tilt speed is represented by a set value of the tilt speed of the polishing head in each polishing process. In the embodiment shown in FIG. 9, the tilt speed is “2000 degrees/minute”.

The number of tilt movements is represented by a set value of the number of tilt movements of the polishing head when the polishing mode is the continuous polishing. In the embodiment shown in FIG. 9, the number of tilt movements in each of the first polishing process and the third polishing process (continuous polishing) is “5 times”. Specifically, as shown in FIG. 6, the polishing head reciprocates five times between the head position G1 and the head position G2.

The angles of inclination α1 to α4 at the head positions G1 to G4 are represented by set values of the angle of inclination of the polishing head at the head positions, respectively. In the embodiment shown in FIG. 9, the angle of inclination α1 at the head position G1 is “60 degrees” and the angle of inclination α2 at the head position G2 is “−60 degrees” in each of the first polishing process and the third polishing process (continuous polishing). Specifically, in the continuous polishing shown in FIG. 6, the angle of inclination α1 at the head position G1 is 60 degrees, and the angle of inclination α2 at the head position G2 is −60 degrees. In each of the second polishing process and the fourth polishing process (fixed polishing), the angle of inclination α1 at the head position G1 is “60 degrees”, the angle of inclination α2 at the head position G2 is “30 degrees”, the angle of inclination α3 at the head position G3 is “−30 degrees”, and the angle of inclination α4 at the head position G4 is “−60 degrees”. Specifically, in the fixed polishing process shown in FIG. 7, the angle of inclination α1 at the head position G1 is 60 degrees, the angle of inclination α2 at the head position G2 is 30 degrees, the angle of inclination α3 at the head position G3 is −30 degrees, and the angle of inclination α4 at the head position G4 is −60 degrees.

The polishing times T1 to T4 at the head positions G1 to G4 are represented by set values of polishing times at the head positions G1 to G4, respectively, when the polishing mode is the fixed polishing. In the embodiment shown in FIG. 9, the polishing times T1 to T4 at the head positions G1 to G4 in each of the second polishing process and the fourth polishing process (fixed polishing) are each “2 seconds”. Specifically, in the fixed polishing process shown in FIG. 7, the polishing heads 33A and 33D are maintained at the head positions G1 to G4 for 2 seconds.

The control system 20 controls the operations of the polishing modules 4A and 4B based on the parameter values included in the preset polishing conditions to cause the polishing modules 4A and 4B to polish the periphery of the substrate.

Next, processing operations of the substrate polishing apparatus shown in FIG. 1 will be described. The processing operations of the substrate polishing apparatus described below include the above-described polishing operations for the periphery of the substrate in the polishing modules 4A and 4B, and are controlled by the control system 20 shown in FIG. 1.

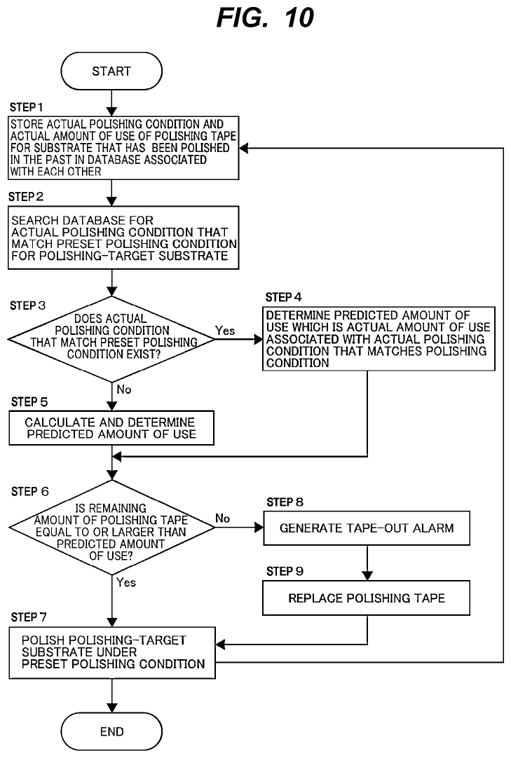

FIG. 10 is a flowchart illustrating an embodiment of the processing operations of the substrate polishing apparatus. The control system 20 stores actual polishing condition and an actual amount of use of the polishing tape for the substrate that has been polished in the past by the polishing module 4A and/or 4B in the database 21a (see FIG. 1), with the actual polishing condition and the actual amount of use of the polishing tape (step 1) associated with each other. In this specification, polishing condition under which the substrate has been polished in the past by the polishing module 4A and/or 4B is referred to as “actual polishing condition”. An amount of use of the polishing tape actually consumed under the actual polishing condition for the substrate that has been polished in the past is referred to as an “actual amount of use”. Storing of the actual polishing condition and the actual amount of use in the database 21a are performed every time one polishing recipe is performed. The substrate that has been polished in the past is at least one substrate, and if a plurality of substrates has been polished in the past, a plurality of actual polishing conditions and a plurality of actual amounts of use are stored in the database 21a.

The control system 20 searches the database 21a for actual polishing condition that matches the preset polishing condition for the polishing-target substrate before polishing of the polishing-target substrate (step 2). When polishing condition that matches the preset polishing condition for the polishing-target substrate exist in the database 21a (“Yes” in step 3), the control system 20 determines a predicted amount of use of the polishing tape to be used for polishing of the polishing-target substrate which is an actual amount of use associated with the actual polishing condition that matches the preset polishing condition for the polishing-target substrate (step 4).

When actual polishing condition that matches the preset polishing condition for the polishing-target substrate does not exist in the database 21a (“No” in the step 3), the control system 20 calculates a predicted amount of use of the polishing tape to be used for polishing of the polishing-target substrate by a method described below to determine the predicted amount of use (step 5).

The control system 20 compares a remaining amount of the polishing tape to be used for polishing of the polishing-target substrate with the predicted amount of use determined in the step 4 or the step 5 (step 6). When the remaining amount of the polishing tape is equal to or larger than the predicted amount of use (“Yes” in the step 6), the control system 20 instructs the polishing module 4A or 4B to polish the polishing-target substrate under the preset polishing condition (step 7). The control system 20 may store actual polishing condition and an actual amount of use when the polishing-target substrate is polished in the database 21a after polishing of the polishing-target substrate (the step 1).

When the remaining amount of the polishing tape to be used for polishing of the polishing-target substrate is smaller than the predicted amount of use (“No” in the step 6), the control system 20 generates a tape-out alarm to urge the user to replace the polishing tape with new one (step 8). After the polishing tape is replaced by the user (step 9) and the tape-out of the polishing tape is removed, the control system 20 instructs the polishing module 4A or the polishing module 4B to polish the polishing-target substrate under the preset polishing condition (the step 7). The control system 20 may store, in the database 21a, actual polishing condition and an actual amount of use when the polishing-target substrate is polished after polishing of the polishing-target substrate (the step 1).

The control system 20 operates according to the instructions contained in the programs electrically stored in the memory 21 (see FIG. 1). Specifically, the control system 20 performs the steps of: storing actual polishing condition for at least one substrate that has been polished in the past and an actual amount of use of the polishing tape under the actual polishing condition in the database 21a, with the actual polishing condition and the actual amount of use associated with each other (see the above-described step 1); searching the database 21a for actual polishing condition that matches the preset polishing condition for the polishing-target substrate before polishing of the polishing-target substrate (see the above-described step 2); determining a predicted amount of use of the polishing tape necessary for polishing the polishing-target substrate which is an actual amount of use of the polishing tape associated with the actual polishing condition that matches the preset polishing condition (see the above-described step 4); comparing the remaining amount of the polishing tape to be used for polishing of the polishing-target substrate with the determined predicted amount of use (see the above-described step 6); and when the remaining amount of the polishing tape is equal to or larger than the predicted amount of use, instructing the polishing module 4A or the polishing module 4B to polish the polishing-target substrate under the preset polishing condition (see the above-described step 7).

When the actual polishing condition that matches the preset polishing condition does not exist in the database 21a, the control system 20 performs the step of calculating the predicted amount of use of the polishing tape based on the preset polishing condition to thereby determine the predicted amount of use of the polishing tape (see the above-described step 5). Further, the control system 20 performs the steps of when the remaining amount of the polishing tape is smaller than the predicted amount of use of the polishing tape to be used for polishing of the polishing-target substrate, generating a tape-out alarm to urge the user to replace the polishing tape (see the above-described step 8); and instructing the polishing module 4A or 4B to polish the polishing-target substrate under the preset polishing condition after the tape-out of the polishing tape is removed (see the above-described step 7).

The programs for causing the control system 20 to perform these steps are stored in a non-transitory tangible computer-readable storage medium, and are provided to the control system 20 via the storage medium. Alternatively, the programs may be input into the control system 20 via a communication network, such as the Internet or a local area network.

The tape feeding speed of the polishing tape when the substrate is polished is actually not constant. In the continuous polishing process, the tape feeding speed may change due to friction when the polishing head is tilted. Further, in the fixed polishing process, the polishing tape is also fed when the polishing head moves between the head positions, and a feeding amount of the polishing tape varies depending on a moving distance between the head positions. Furthermore, the polishing tape is also fed during a transition period between the continuous polishing process and the fixed polishing process. Therefore, it is difficult to accurately calculate the predicted amount of use of the polishing tape with conventional techniques.

Thus, the substrate polishing apparatus of this embodiment uses, as the predicted amount of use of the polishing tape, the actual amount of use of the polishing tape associated with the actual polishing condition that matches the polishing condition for the polishing-target substrate. Therefore, the substrate polishing apparatus can determine an accurate predicted amount of use of the polishing tape which reflects a change in tape feeding speed during polishing of the substrate, the feeding amount of the polishing tape when the polishing head moves between the head positions, and the feeding amount of the polishing tape in the transition period between different polishing processes. In addition, the substrate polishing apparatus can consume as much polishing tape as possible and eliminate a tape end error by comparing the remaining amount of the polishing tape with the determined predicted amount of use before polishing of the polishing-target substrate. As a result, the number of substrates which are discarded can be reduced.

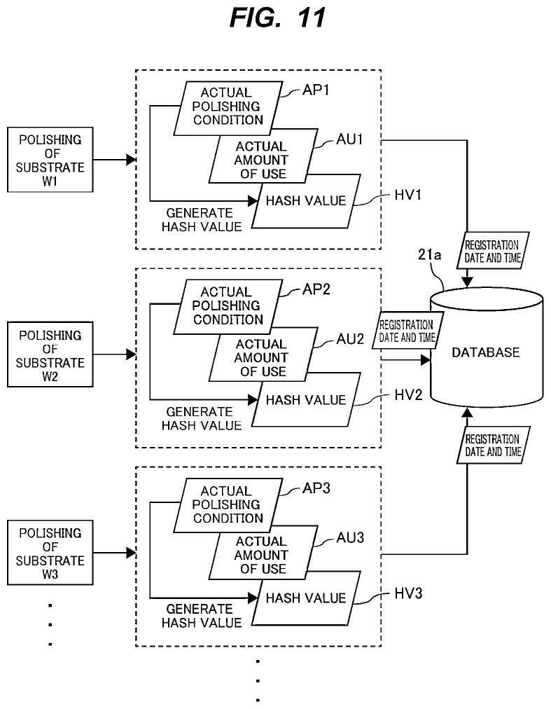

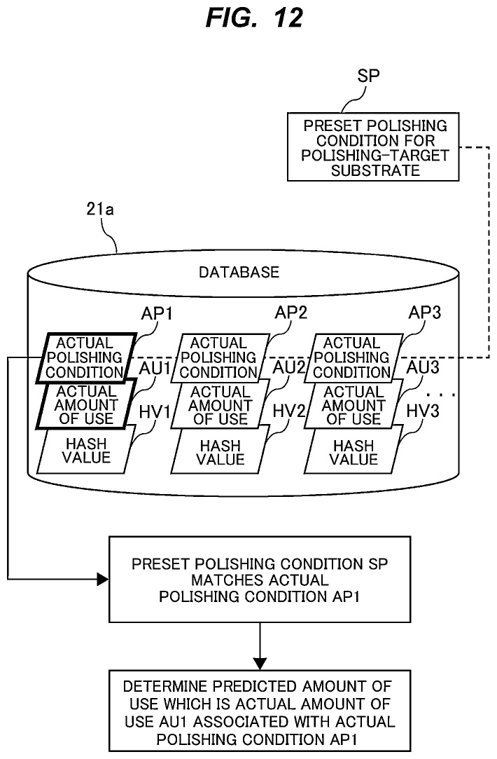

Next, details of each of the above-described processing operations will be described. FIG. 11 is a diagram illustrating a process of storing actual polishing conditions AP1. AP2, and AP3 for substrates W1, W2, and W3 that have been polished in the past, and actual amounts of use AU1, AU2, and AU3 of the polishing tape in the database 21a (see the step 1 in FIG. 10). As shown in FIG. 11, when polishing of the substrate W1 is terminated, the control system 20 stores the actual polishing condition AP1 and the actual amount of use AU1 of the polishing tape used in polishing of the substrate W1 in the database 21a. For example, as described with reference to FIG. 8, when the polishing process of the substrate W1 includes the first polishing process to the fourth polishing process, the control system 20 stores the actual polishing condition AP1 and the actual amount of use AU1 of the polishing tapes 32A, 32C, and 32D in the database 21a after the fourth polishing process is terminated.

The actual polishing condition AP1 for polishing of the substrate W1 includes the polishing conditions for the first polishing process to the fourth polishing process. As described with reference to FIG. 9, the actual polishing condition includes at least one of the recipe name, the recipe update date and time, the polishing-module identifier, the polishing-head identifier, the polishing-tape identifier, the polishing mode, the tape feeding speed, the tilt speed, the number of tilt movements, the angles of inclination α1 to α4 at the head positions, and the polishing times T1 to T4 at the head positions.

The actual amount of use of the polishing tape is calculated for each polishing head used in polishing of the substrate. Specifically, in the polishing of the substrate W1, an amount of the polishing tape 32A actually used by the polishing head 33A in the first polishing process and the second polishing process, an amount of the polishing tape 32C actually used by the polishing head 33C in the third polishing process, and an amount of the polishing tape 32D actually used by the polishing head 33D in the fourth polishing process are calculated.

The rotary encoder (not shown) attached to the tape advancing motor M (see FIG. 4) of each of the polishing heads 33A to 33D is configured to count the number of rotations of the tape advancing motor M. The control system 20 calculates the actual amounts of use of the polishing tapes 32A to 33D from the numbers of rotations of the tape advancing motors M of the polishing heads 33A to 33D and a circumferential length of the tape advancing roller 56a (see FIG. 4). For example, if the tape advancing motor M of the polishing head 33A rotates 5.7 times during the first polishing process and the second polishing process, the control system 20 can calculate the actual amount of use of the polishing tape 32A by multiplying the circumferential length of the tape advancing roller 56a by 5.7.

Similarly, when the polishing of the substrate W2 is terminated, the control system 20 stores the actual polishing condition AP2 and the actual amount of use AU2 of the polishing tape used in polishing of the substrate W2 in the database 21a. Further, when the polishing of the substrate W3 is terminated, the control system 20 stores the actual polishing condition AP3 and the actual amount of use AU3 of the polishing tape used in polishing of the substrate W3 in the database 21a. The control system 20 may associate the actual polishing condition and the actual amount of use with a registration date and time indicating date and time at which the actual polishing condition and the actual amount of use are stored in the database 21a, and may store the registration date and time together with the actual polishing condition and the actual amount of use in the database 21a.

The control system 20 may generate hash values HV1, HV2, and HV3 corresponding to the actual polishing conditions AP1, AP2, and AP3 by the arithmetic device 22 (see FIG. 1), respectively, and may store the actual polishing conditions AP1, AP2, and AP3 together with the generated hash values HV1, HV2, and HV3 in the database 21a in association with each other. The hash value is an identifier generated according to an algorithm contained in the programs stored in the memory 21 (see FIG. 1) based on the parameter values of each of the actual polishing conditions. The hash value is composed of numerical values, characters, or a combination thereof, and uniquely corresponds to a combination of a plurality of parameter values of each of the actual polishing conditions. The control system 20 can speed up the process of searching the database 21a for the actual polishing condition that matches the polishing condition for the polishing-target substrate by using the hash values.

In one embodiment, when the actual polishing condition includes polishing conditions for polishing processes with use of a plurality of polishing heads, the control system 20 may generate a plurality of hash values corresponding to the actual polishing condition for the plurality of polishing heads, respectively. The plurality of hash values generated for the plurality of polishing heads are associated with the plurality of polishing heads, respectively. Further, the control system 20 may store the actual amount of use of the polishing tape calculated for each polishing head and the hash value generated for each polishing head in the database 21a in association with each other.

For example, as described with reference to FIG. 8, when the actual polishing condition AP1 for the substrate W1 includes the polishing conditions for the first polishing process to the fourth polishing process, the same number of hash values as the number of the polishing heads are generated for the polishing heads 33A, 33C, and 33D. More specifically, the control system 20 generates three hash values including a hash value associated with the polishing head 33A corresponding to the actual polishing conditions for the first polishing process and the second polishing process, a hash value associated with the polishing head 33C corresponding to the actual polishing condition for the third polishing process, and a hash value associated with the polishing head 33D corresponding to the actual polishing condition for the fourth polishing process.

Further, the control system 20 stores the actual amount of use of the polishing tape 32A for the polishing head 33A and the hash value associated with the polishing head 33A in the database 21a in association with each other, stores the actual amount of use of the polishing tape 32C for the polishing head 33C and the hash value associated with the polishing head 33C in the database 21a in association with each other, and stores the actual amount of use of the polishing tape 32D for the polishing head 33D and the hash value associated with the polishing head 33C in the database 21a in association with each other.

In this manner, the control system 20 stores the actual polishing condition, the actual amount of use of the polishing tape, and the hash value in the database 21a every time all polishing processes for one substrate are terminated. The database 21a is constructed in the memory 21 with the data of the actual polishing conditions for substrates that have been polished in the past, the actual amounts of use of polishing tape, and the hash values. The arithmetic device 22 can read the actual polishing condition, the actual amounts of use, and the hash values stored in the database 21a.

FIG. 12 is a diagram illustrating a process of searching the database 21a for an actual polishing condition that matches the preset polishing condition for the polishing-target substrate and determining a predicted amount of use (see the steps 2 to 4 in FIG. 10). As described with reference to FIG. 11, the database 21a shown in FIG. 12 stores therein the data including the actual polishing condition AP1 for the substrate W1 that has been polished in the past, the actual amount of use AU1 of the polishing tape, the hash value HV1, the actual polishing condition AP2 for the substrate W2 that has been polished in the past, the actual amount of use AU2 of the polishing tape, the hash value HV2, the actual polishing condition AP3 for the substrate W3 that has been polished in the past, the actual amount of use AU3 of the polishing tape, and the hash value HV3.

The control system 20 searches the database 21a for the actual polishing condition that matches the preset polishing condition for the polishing-target substrate before polishing of the polishing-target substrate. As described with reference to FIG. 9, the preset polishing condition for the polishing-target substrate includes at least one of the recipe name, the recipe update date and time, the polishing-module identifier, the polishing-head identifier, the polishing-tape identifier, the polishing mode, the tape feeding speed, the tilt speed, the number of tilt movements, the angles of inclination α1 to α4 at the head positions, and the polishing times T1 to T4 at the head positions.

When the actual polishing condition that matches the preset polishing condition of the polishing-target substrate exist in the database 21a, the control system 20 determines a predicted amount of use of the polishing tape to be used for polishing of the polishing-target substrate which is the actual amount of use associated with the actual polishing condition that matches the preset polishing condition. For example, as shown in FIG. 12, when a preset polishing condition SP matches the actual polishing condition AP1 stored in the database 21a, the control system 20 determines that the actual amount of use AU1 associated with the actual polishing condition AP1 is the predicted amount of use of the polishing tape to be used for polishing of the target substrate.

The preset polishing condition for the polishing-target substrate for use in the search includes at least one of the recipe name, the recipe update date and time, the polishing-module identifier, the polishing-head identifier, the polishing-tape identifier, the polishing mode, the tape feeding speed, the tilt speed, the number of tilt movements, the angles of inclination α1 to α4 at the head positions, and the polishing times T1 to T4 at the head positions. The polishing condition for use in the search may be only the recipe name, or may be a part of the parameters of the polishing condition. The user can arbitrarily select the polishing condition for use in the search with use of the input device (not shown) of the control system 20.

For example, when the search is performed using the recipe name, a plurality of recipe names that match the recipe name of the preset polishing condition for the polishing-target substrate may exist in the database 21a. The control system 20 may determine an actual polishing condition with the latest recipe-updated date and time from the plurality of actual polishing conditions that match the preset polishing condition.

In addition, when the search is performed using the recipe name, even if the recipe name of the preset polishing condition for the polishing-target substrate matches the recipe name of the actual polishing condition, value(s) of the polishing condition associated with the recipe name may have been changed in the past, and the values of the polishing condition and the values of the actual polishing condition may not actually match. In order to determine an accurate predicted amount of use, all values of the polishing condition for the polishing-target substrate must match all values of the actual polishing condition for the substrate that has been polished in the past. However, if all values of the polishing condition are used in the search, an amount of data is enormous, so that a processing load on the control system 20 may increase. Thus, the control system 20 can speed up the searching process by generating a hash value of the polishing condition and using the hash value as a searching hash value.

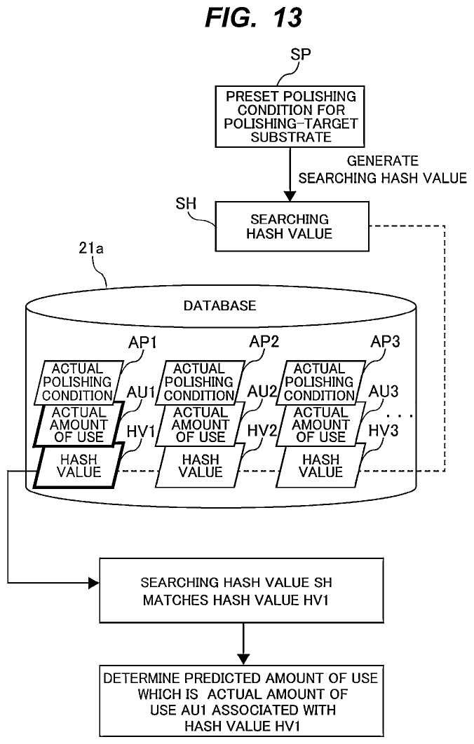

FIG. 13 is a diagram illustrating a method of searching using a searching hash value. The control system 20 may generate a searching hash value SH corresponding to the preset polishing condition SP for the polishing-target substrate by the arithmetic device 22 (see FIG. 1). The searching hash value SH is an identifier generated according to an algorithm contained in the programs stored in the memory 21 (see FIG. 1) based on the parameter values of the preset polishing condition for the polishing-target substrate. This algorithm is the same as the algorithm for generating the hash values stored in the database 21a described with reference to FIG. 11.

When a hash value that matches the searching hash value SH exists in the database 21a, the control system 20 determines the predicted amount of use of the polishing tape to be used for polishing of the polishing-target substrate which is the actual amount of use associated with the hash value that matches the searching hash value SH. For example, as shown in FIG. 13, when the searching hash value SH matches the hash value HV1 stored in the database 21a, the control system 20 determines that the actual amount of use AU1 associated with the hash value HV1 is the predicted amount of use of the polishing tape to be used for polishing of the polishing-target substrate.

In one embodiment, when the preset polishing condition includes polishing conditions for polishing processes with use of a plurality of polishing heads, the control system 20 may generate a plurality of searching hash values corresponding respectively to the preset polishing conditions for the plurality of polishing heads. The plurality of searching hash values generated for the plurality of polishing heads are associated with the plurality of polishing heads, respectively. Further, when a hash value that matches the searching hash value generated for each polishing head exists in the database 21a, the control system 20 may determine that an actual amount of use of the polishing tape associated with the hash value that matches the searching hash value generated for each polishing head is the predicted amount of use of the polishing tape to be used for polishing of the polishing-target substrate.

Next, a method of determining the predicted amount of use of the polishing tape to be used for polishing of the polishing-target substrate when the actual polishing condition that matches the preset polishing condition for the polishing-target substrate does not exist in the database 21a will be described (see the step 5 in FIG. 10). When the actual polishing condition that matches the preset polishing condition for the polishing-target substrate does not exist in the database 21a, the control system 20 calculates the predicted amount of use of the polishing tape based on the preset polishing condition.

The method of calculating the predicted amount of use of the polishing tape varies depending on the polishing mode. When the polishing mode is the continuous polishing, the predicted amount of use is calculated from the tape feeding speed, the tilt speed, the number of tilt movements, the angle of inclinational at the head position G1, and the angle of inclination α2 at the head position G2 of the preset polishing condition for the polishing-target substrate (see FIG. 6). A tilting time Ta required for tilting from the angle of inclination α1 at the head position G1 to the angle of inclination α2 at the head position G2 is determined by dividing a value, which is obtained by subtracting the angle of inclination α2 at the head position G2 from the angle of inclination α1 at the head position G1, by the tilt speed TS (Ta=(a1−α2)/TS). Since the tilting time Ta corresponds to half of the time required for the polishing head to make one reciprocation between the head position G1 and the head position G2, the time required for the polishing head to make one reciprocation is two times the tilting time Ta. Therefore, a predicted amount of use EUa in the continuous polishing is calculated by multiplying a value, which is obtained by multiplying a value of two times the tilting time Ta by the number of tilt movements TC, by the tape feeding speed FS (EUa=Ta×2×TC×FS).

When the polishing mode is the fixed polishing, the predicted amount of use is calculated from the tape feeding speed, the polishing time T1 at the head position G1, the polishing time T2 at the head position G2, the polishing time T3 at the head position G3, and the polishing time T4 at the head position G4 of the preset polishing condition for the polishing-target substrate (see FIG. 7). A total polishing time is calculated by adding up all the polishing times T1 to T4 at the head position G1 to G4. Therefore, a predicted amount of use EUb in the fixed polishing is calculated by multiplying a value of the sum of all the polishing times T1 to T4 by the tape feeding speed FS (EUb=(T1+T2+T3+T4)×FS).

Next, a process of comparing the remaining amount of the polishing tape with the determined predicted amount of use (see the step 6 in FIG. 10) will be described. The control system 20 stores an initial length of a new polishing tape in the memory 21 when the polishing tape is replaced with the new polishing tape. The initial length is obtained in advance from specifications provided by a manufacturer of the polishing tape. The remaining amount of the polishing tape is calculated by subtracting the actual amount of use of the polishing tape used in the past polishing from the initial length every time polishing of the substrate using the polishing tape is completed. The control system 20 compares the calculated remaining amount of the polishing tape with the determined predicted amount of use.

The comparison of the remaining amount of the polishing tape with the determined predicted amount of use is performed for each of the polishing heads 33A to 33D. More specifically, the control system 20 compares the remaining amounts of the polishing tapes 32A to 32D fed to the polishing heads 33A to 33D with the predicted amounts of use corresponding to the polishing tapes 32A to 32D, respectively. When all the remaining amounts of the polishing tapes 32A to 32D fed to the polishing heads 33A to 33D are equal to or larger than the corresponding predicted amounts of use, the control system 20 performs polishing of the polishing-target substrate under the preset polishing condition by the polishing modules 4A and 4B. If any one of the remaining amounts of the polishing tapes 32A to 32D is smaller than the corresponding predicted amount of use, the control system 20 generates a tape-out alarm for the corresponding polishing head to urge the user to replace the polishing tape.

The substrate polishing apparatus of the embodiment shown in FIG. 1 can simultaneously polish a plurality of substrates. Therefore, at the point in time when the control system 20 compares the remaining amount of the polishing tape with the determined predicted amount of use, other substrate(s) before or during polishing may be present in the substrate polishing apparatus, in addition to the polishing-target substrate. In this case, the actual amount of the polishing tape used for the other substrate(s) before or during polishing is not reflected in the remaining amount of the polishing tape. The control system 20 may calculate the remaining amount of the polishing tape by subtracting both the actual amount of use of the polishing tape used in the past polishing and the predicted amount of use of the polishing tape for the other substrate(s) before or during polishing from the initial length.

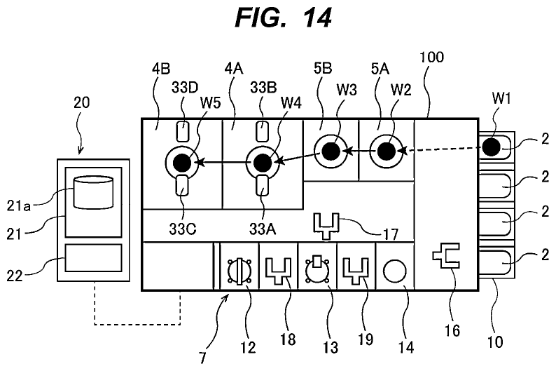

FIG. 14 is a plan view showing an embodiment of arrangements of a plurality of polishing-target substrates W1 to W5. The substrate W1 is placed in the substrate cassette 2 of the load port 10. The substrate W2 is placed on the waiting stage 5A. The substrate W3 is placed on the waiting stage 5B. The substrate W4 is being polished by the polishing head 33A of the polishing module 4A. The substrate W5 is being polished by the polishing head 33C of the polishing module 4B.

In this embodiment, each of the substrates W1, W2, W3, W4, and W5 is polished in the same manner by the polishing modules 4A and 4B. More specifically, each of the substrates W1, W2, W3, W4, and W5 is polished by the polishing head 33A and the polishing head 33B of the polishing module 4A, and is then polished by the polishing head 33C and the polishing head 33D of the polishing module 4B. The substrates W1, W2, and W3 shown in FIG. 14 are in a state before polishing, and the substrates W4 and W5 are in a state being polished.

The substrate W5 is polished by the polishing head 33C of the polishing module 4B, and is then polished by the polishing head 33D. When the polishing of the substrate W5 is completed, the substrate W5 is transported from the polishing module 4B to the cleaning-drying section 7 by the second transfer robot 17. Thereafter, the substrate W5 is cleaned and dried by the cleaning-drying section 7.

The substrate W4 is polished by the polishing head 33A of the polishing module 4A, and is then polished by the polishing head 33B. After the polishing of the substrate W4 is completed and the substrate W5 is removed from the polishing module 4B, the second transfer robot 17 transports the substrate W4 from the polishing module 4A to the polishing module 5A. Thereafter, the substrate W4 is polished by the polishing head 33C of the polishing module 4B, and is further polished by the polishing head 33D.

After the substrate W4 is removed from the polishing module 4A, the substrate W3 is transported from the waiting stage 5B to the polishing module 4A by the second transfer robot 17. Thereafter, the substrate W3 is polished by the polishing head 33A of the polishing module 4A, and is further polished by the polishing head 33B.

After the substrate W3 is removed from the waiting stage 5B, the substrate W2 is transported from the waiting stage 5A to the waiting stage 5B by the second transfer robot 17. After the substrate W2 is removed from the waiting stage 5A, the substrate W1 is transported to the second transfer robot 17 by the first transfer robot 16, and is placed on the waiting stage 5A by the second transfer robot 17. In this way, the plurality of substrates W1 to W5 are moved in an order of the load port 10, the waiting stage 5A, the waiting stage 5B, the polishing module 4A, the polishing module 4B, and the cleaning-drying section 7 and are processed.

The operations of the steps 2 to 6 described with reference to FIG. 10 are performed before the plurality of polishing-target substrates W1 to W5 is transported from the substrate cassette 2 of the load port 10. The control system 20 determines the predicted amounts of use of the polishing tapes 32A to 32D to be used by the polishing heads 33A to 33D. When all the remaining amounts of the polishing tapes 32A to 32D are equal to or larger than the predicted amounts of use of the polishing tapes 32A to 32D, respectively, the control system 20 instructs the first transfer robot 16 to transport the substrate W1 shown in FIG. 14 from the substrate cassette 2 to the second transfer robot 17.

At the point in time when the control system 20 compares the remaining amounts of the polishing tapes 32A to 32D with the determined predicted amounts of use, polishing of the substrates W2, W3, W4, and W5 have not been terminated, so that the actual amounts of use of the polishing tapes 32A to 32D to be used for polishing of the substrates W2 to W5 are not determined. The control system 20 calculates the remaining amounts of the polishing tapes 32A to 32D by subtracting the predicted amounts of use of the polishing tapes 32A to 32D for the substrates W2 to W5 from current remaining amounts of the polishing tapes 32A to 32D, respectively. The control system 20 compares the resultant remaining amounts of the polishing tapes 32A to 32D with the determined predicted amounts of use of the polishing tapes 32A to 32D, respectively.

According to the present embodiment, before polishing of the polishing-target substrate, even if other substrate(s) before or during polishing are present, the control system 20 compares the remaining amount of the polishing tape, which reflects the predicted amount of use of the polishing tape, with the predicted amount of use of the polishing tape for the polishing-target substrate. Therefore, the polishing tape can be consumed as much as possible, and the tape-end error can be eliminated. As a result, the number of substrates which are discarded can be reduced.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a substrate polishing method of polishing a substrate by pressing a polishing tape against the substrate. Further, the present invention is applicable to a substrate polishing apparatus including a polishing module configured to polish a substrate by pressing a polishing tape against the substrate. Furthermore, the present invention is applicable to a program for polishing a substrate with a polishing tape.

### REFERENCE SIGNS LIST

2 substrate cassette
4A, 4B polishing module
5A, 5B waiting stage
7 cleaning-drying section
10 load port
12 first cleaning module
13 second cleaning module
14 drying module
16 first transfer robot
17 second transfer robot
18 third transfer robot
19 fourth transfer robot
20 control system
21 memory
21a database
22 arithmetic device
32A, 32B, 32C. 32D polishing tape
33A, 33B, 33C. 33D polishing head
34 holding stage
35 shaft
37 holding-stage driving mechanism
40 substrate holder
42 lower supply nozzle
43 upper supply nozzle
46A, 46B polishing-tape feeding mechanism
47 tape feeding reel
48 tape take-up reel
50, 51, 52, 53 guide roller
54 air cylinder
56 tape advancing device
56a tape advancing roller
56b tape holding roller
60, 61, 62, 63, 64, 65, 66 guide roller
68 pressing member
70A, 70B tilting mechanism
72 crank arm
73 arm rotating device
100 housing
M tape advancing motor

1. A substrate polishing method comprising:
storing, in a database, an actual polishing condition for at least one substrate that has been polished in the past and an actual amount of use of a polishing tape under the actual polishing condition, with the actual polishing condition and the actual amount of use associated with each other;
searching the database for an actual polishing condition that matches a preset polishing condition for a polishing-target substrate before polishing of the polishing-target substrate;
determining a predicted amount of use of a polishing tape necessary for polishing the polishing-target substrate which is an actual amount of use of the polishing tape associated with the actual polishing condition that matches the preset polishing condition;
comparing a remaining amount of the polishing tape to be used for polishing of the polishing-target substrate with the determined predicted amount of use; and
when the remaining amount of the polishing tape is equal to or larger than the predicted amount of use, polishing the polishing-target substrate by a polishing module.

2. The substrate polishing method according to claim 1,
wherein determining the predicted amount of use comprises, when an actual polishing condition that matches the preset polishing condition does not exist in the database, determining the predicted amount of use by calculating the predicted amount of use of the polishing tape to be used for polishing of the polishing-target substrate based on the preset polishing condition.

3. The substrate polishing method according to claim 1, wherein the actual polishing condition includes a polishing-head identifier for identifying a polishing head of a plurality of polishing heads that has been used in polishing of at least one substrate in the past, and
the preset polishing condition includes a polishing-head identifier for identifying a polishing head to be used for polishing of the polishing-target substrate.

4. The substrate polishing method according to claim 1, wherein the actual polishing condition includes a polishing-tape identifier for identifying a type of polishing tape of a plurality of types of polishing tapes that has been used in polishing of at least one substrate in the past, and
the preset polishing condition includes a polishing-tape identifier for identifying a type of polishing tape to be used for polishing of the polishing-target substrate.

5. The substrate polishing method according to claim 1, wherein the actual polishing condition comprises polishing conditions for a plurality of polishing processes performed in polishing of at least one substrate that has been polished in the past,
the actual amount of use comprises an actual amount of use of a polishing tape that has been used from start to end of polishing including the plurality of polishing processes, and
the preset polishing condition comprises polishing conditions for a plurality of polishing processes applied to polishing of the polishing-target substrate.

6. The substrate polishing method according to claim 1, further comprising:
generating a hash value corresponding to the actual polishing condition and storing the actual amount of use and the hash value in the database, with the actual amount of use and the hash value associated with each other; and
generating a searching hash value corresponding to the preset polishing condition for the polishing-target substrate and searching the database for a hash value that matches the searching hash value,
wherein determining the predicted amount of use comprises determining the predicted amount of use of the polishing tape necessary for polishing the polishing-target substrate which is an actual amount of use of the polishing tape associated with the hash value that matches the searching hash value.

7. A substrate polishing apparatus comprising:
a polishing module configured to polish a substrate with a polishing tape; and
a control system including a database and an arithmetic device,
wherein the control system is configured to:
store, in the database, an actual polishing condition for at least one substrate that has been polished in the past and an actual amount of use of a polishing tape under the actual polishing condition, with the actual polishing condition and the actual amount of use associated with each other;
search the database for an actual polishing condition that matches a preset polishing condition for a polishing-target substrate before polishing of the polishing-target substrate;
determine a predicted amount of use of the polishing tape necessary for polishing the polishing-target substrate which is an actual amount of use of the polishing tape associated with the actual polishing condition that matches the preset polishing condition;
compare a remaining amount of the polishing tape to be used for polishing of the polishing-target substrate with the determined predicted amount of use; and
when the remaining amount of the polishing tape is equal to or larger than the predicted amount of use, instruct the polishing module to polish the polishing-target substrate.

8. The substrate polishing apparatus according to claim 7, wherein the control system is configured to calculate the predicted amount of use of the polishing tape to be used for polishing of the polishing-target substrate based on the preset polishing condition when an actual polishing condition that matches the preset polishing condition does not exist in the database.

9. The substrate polishing apparatus according to claim 7, wherein the actual polishing condition includes a polishing-head identifier for identifying a polishing head of a plurality of polishing heads that has been used in polishing of at least one substrate in the past, and
the preset polishing condition includes a polishing-head identifier for identifying a polishing head to be used for polishing of the polishing-target substrate.

10. The substrate polishing apparatus according to claim 7, wherein the actual polishing condition includes a polishing-tape identifier for identifying a type of polishing tape of a plurality of types of polishing tapes that has been used in polishing of at least one substrate in the past, and
the preset polishing condition includes a polishing-tape identifier for identifying a type of polishing tape to be used for polishing of the polishing-target substrate.

11. The substrate polishing apparatus according to claim 7, wherein the actual polishing condition comprises polishing conditions for a plurality of polishing processes performed in polishing of at least one substrate that has been polished in the past,
the actual amount of use comprises an actual amount of use of a polishing tape that has been used from start to end of polishing including the plurality of polishing processes, and
the preset polishing condition comprises polishing conditions for a plurality of polishing processes applied to polishing of the polishing-target substrate.

12. The substrate polishing apparatus according to claim 7, wherein the control system is configured to:
generate a hash value corresponding to the actual polishing condition and store the actual amount of use and the hash value in the database, with the actual amount of use and the hash value associated with each other;
generate a searching hash value corresponding to the preset polishing condition for the polishing-target substrate and search the database for a hash value that matches the searching hash value; and
determine the predicted amount of use of the polishing tape necessary for polishing the polishing-target substrate which is an actual amount of use of the polishing tape associated with the hash value that matches the searching hash value.

13. A computer-readable storage medium storing a program for instructing a control system to perform the steps of:
storing, in the database, an actual polishing condition for at least one substrate that has been polished in the past and an actual amount of use of a polishing tape under the actual polishing condition, with the actual polishing condition and the actual amount of use associated with each other;
searching the database for an actual polishing condition that matches a preset polishing condition for a polishing-target substrate before polishing of the polishing-target substrate;
determining a predicted amount of use of the polishing tape necessary for polishing the polishing-target substrate which is an actual amount of use of the polishing tape associated with the actual polishing condition that matches the preset polishing condition;
comparing a remaining amount of the polishing tape to be used for polishing of the polishing-target substrate with the determined predicted amount of use; and
when the remaining amount of the polishing tape is equal to or larger than the predicted amount of use, instructing a polishing module to polish the polishing-target substrate.
